(19) United States
(12) Patent Application Publication
(10) Pub. No.: US 2025/0020998 A1
(43) Pub. Date: Jan. 16, 2025

(54) PHOTORESIST COMPOSITIONS AND METHODS OF MANUFACTURING INTEGRATED CIRCUIT DEVICES USING THE SAME

(71) Applicant: Samsung Electronics Co., Ltd., Suwon-si (KR)

(72) Inventors: Kyungoh Kim, Suwon-si (KR); Jaemyoung Kim, Suwon-si (KR); Seungwook Shin, Yongin si (KR); Wanhee Lim, Yongin si (KR); Moohyun Koh, Suwon-si (KR); Minsoo Kim, Yongin si (KR); Seungwoo Jang, Yongin si (KR); Suk Koo Hong, Suwon-si (KR)

(73) Assignees: Samsung Electronics Co., Ltd., Suwon-si (KR); Samsung SDI Co., Ltd., Yongin-si (KR)

(21) Appl. No.: 18/633,948

(22) Filed: Apr. 12, 2024

(30) Foreign Application Priority Data
Jul. 6, 2023 (KR) 10-2023-0087954

(51) Int. Cl. G03F 7/004; H01L 21/027; H01L 21/308; H01L 21/311; H01L 21/3213

(52) U.S. Cl. CPC G03F 7/0044; H01L 21/0275; H01L 21/3081; H01L 21/3086; H01L 21/31144; H01L 21/32139

(57) ABSTRACT

A photoresist composition includes an organometallic compound, which includes at least one metal-ligand bond including a metal core and at least one organic ligand bonded to the metal core; at least one first organic ligand precursor, which is different in chemical structure from the at least one organic ligand of the organometallic compound, and which includes a phosphonic acid group and has a structure capable of forming a coordination complex with the metal core; and a solvent. A method of manufacturing an integrated circuit device includes forming a photoresist film on a substrate using the photoresist composition, and forming a modified organometallic compound by binding an organic ligand including a phosphonic acid group to the organometallic compound through a ligand exchange between the organometallic compound and the at least one first organic ligand precursor based on chemical equilibrium in the photoresist film.

### CROSS-REFERENCE TO RELATED APPLICATION

This application claims priority under 35 U.S.C. § 119 to Korean Patent Application No. 10-2023-0087954, filed on Jul. 6, 2023, in the Korean Intellectual Property Office, the disclosure of which is incorporated by reference herein in its entirety.

### FIELD

The inventive concept relates to a photoresist composition and a method of manufacturing an integrated circuit device by using the photoresist composition, and more particularly, to a photoresist composition including a metal, and a method of manufacturing an integrated circuit device by using the photoresist composition.

### BACKGROUND

Due to the advance of electronics technology, semiconductor devices have been rapidly down-scaled. Therefore, photolithography processes having an advantage in implementing fine patterns are desired. In particular, there is a need to develop photoresist compositions capable of providing process stability, excellent etch resistance, and excellent resolution in photolithography processes for manufacturing integrated circuit devices.

### SUMMARY

The inventive concept provides a photoresist composition, which may improve process stability by suppressing a change over time and may provide excellent etch resistance and excellent resolution in a photolithography process of manufacturing an integrated circuit device.

The inventive concept also provides a method of manufacturing an integrated circuit device, the method may allow for process stability to be improved by suppressing a change over time in a photolithography process and may allow dimensional precision of a pattern intended to be formed to be improved by providing excellent etch resistance and excellent resolution in a photolithography process.

According to an aspect of the inventive concept, there is provided a photoresist composition including an organometallic compound, which includes at least one metal-ligand bond including a metal core and at least one organic ligand bonded to the metal core; at least one first organic ligand precursor that is different in chemical structure from the at least one organic ligand of the organometallic compound, includes a phosphonic acid group, and has a structure capable of forming (e.g., configured to form and/or that can form) a coordination complex with the metal core, and a solvent.

According to another aspect of the inventive concept, there is provided a photoresist composition including an organometallic compound, which includes a metal core and a plurality of organic ligands bonded to the metal core; at least one first organic ligand precursor, which is different in chemical structure from the plurality of organic ligands of the organometallic compound, the at least one first organic ligand precursor comprising a phosphonic acid group and having a structure capable of forming a coordination complex with the metal core; and a solvent, wherein one organic ligand selected from the plurality of organic ligands is a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, or a substituted or unsubstituted C7 to C30 arylalkyl group, and the other organic ligands of the plurality of organic ligands, are each independently an R³⁷COO— group (where each R³⁷ is independently a substituted or unsubstituted C1 to C10 alkyl group or a substituted or unsubstituted phenyl group), and a molar ratio of the at least one first organic ligand precursor to the organometallic compound is about 0.01 to about 10.

According to another aspect of the inventive concept, there is provided a method of manufacturing an integrated circuit device, the method including forming a photoresist film on a substrate using a photoresist composition including an organometallic compound, at least one first organic ligand precursor, and a solvent, the organometallic compound including a metal core and a plurality of organic ligands, that are each bonded to the metal core and are each devoid of a phosphonic acid group, wherein the at least one first organic ligand precursor is different in chemical structure than the plurality of organic ligands of the organometallic compound, includes a phosphonic acid group, and has a structure capable of forming a coordination complex with the metal core. The method further comprises forming a modified organometallic compound by binding an organic ligand including a phosphonic acid group to the organometallic compound through a ligand exchange between the organometallic compound and the at least one first organic ligand precursor based on chemical equilibrium in the photoresist film; exposing a first region, which is a portion of the photoresist film, to light to provide an exposed first region forming a metal structure network in the first region by inducing a dissociation reaction of the organic ligand from the modified organometallic compound in the first region through bake of the photoresist film including the exposed first region and by inducing a condensation reaction of a hydroxyl (—OH) functional group generated at a site from which the organic ligand is dissociated in the modified organometallic compound; and forming a photoresist pattern including the metal structure network by developing the photoresist film in which the metal structure network is formed.

### BRIEF DESCRIPTION OF THE DRAWINGS

Embodiments will be more clearly understood from the following detailed description taken in conjunction with the accompanying drawings in which:

FIG. 1 is a flowchart illustrating a method of manufacturing an integrated circuit device, according to some embodiments; and

FIGS. 2A to 2F are cross-sectional views illustrating aspects of a method of manufacturing an integrated circuit device, according to some embodiments.

### DETAILED DESCRIPTION OF THE EMBODIMENTS

Hereinafter, embodiments of the inventive concept will be described in detail with reference to the accompanying drawings. Like components are denoted by like reference numerals throughout the specification, and repeated descriptions thereof are omitted.

A photoresist composition according to some embodiments may include an organometallic compound, at least one first organic ligand precursor, and a solvent, the organometallic compound including at least one metal-ligand bond that is between a metal core and at least one organic ligand. In the photoresist composition according to some embodiments, the at least one first organic ligand precursor may have a chemical structure that is different than that of the at least one organic ligand of the organometallic compound, and the at least one first organic ligand may include a phosphonic acid group. The at least one first organic ligand precursor may have a structure capable of forming (e.g., configured to form and/or can form) a coordination complex with the metal core of the organometallic compound precursor.

In the photoresist composition according to some embodiments, when the organometallic compound is exposed to light of one selected from a KrF excimer laser (248 nm), an ArF excimer laser (193 nm), an F₂ excimer laser (157 nm), and an extreme ultraviolet (EUV) laser (13.5 nm), the organometallic compound may absorb the light, and due to energy absorbed as such, the bond between the metal core and the at least one organic ligand may be broken by a mutual reaction between the metal core and the at least one organic ligand bonded to the metal core.

In the photoresist composition according to some embodiments, the metal core of the organometallic compound may include at least one metal element. The at least one metal element may be in the form of a metal atom, a metallic ion, a metal compound, a metal alloy, or a combination thereof. The metal compound may include a metal oxide, a metal nitride, a metal oxynitride, a metal silicide, a metal carbide, or a combination thereof. In some embodiments, the metal core may include, but is not limited to, at least one metal element selected from Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, and Fe.

In the photoresist composition according to some embodiments, the at least one first organic ligand precursor may include an organic sulfonic acid compound represented by General Formula 1.

$${R}^{1} — P ( = O ) {( OH )}_{2} \qquad [ General Formula 1 ]$$

In General Formula 1, R¹ may be an aliphatic hydrocarbon group or an aromatic hydrocarbon group selected from a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, and a substituted or unsubstituted C7 to C30 alkylaryl group.

In General Formula 1, when R¹ has a substituted hydrocarbon group, all or some hydrogen atoms, which are included in the hydrocarbon group of R¹, may independently be substituted with a halogen atom, a hydroxyl group, a sulfonic acid group, a carboxyl group, an amino group, a thiol (—SH) group, an R¹¹SO₃— group, or an R¹²SO₂— group. Here, each of R¹¹ and R¹² is a hydrogen atom, a substituted or unsubstituted C1 to C10 alkyl group, or a substituted or unsubstituted phenyl group to thereby provide the substituted hydrocarbon group.

The at least one first organic ligand precursor, which is included in the photoresist composition according to some embodiments, may have a structure capable of forming a coordination complex with the metal core of the organometallic compound. When the at least one first organic ligand precursor forms a coordination complex with the metal core, the at least one first organic ligand precursor may have a structure having at least one binding site for the metal core. In some embodiments, the compound represented by General Formula 1 may be a compound capable of being (e.g. configured to and/or can be) coordination-bonded to the metal core. When the compound represented by General Formula 1 is coordination-bonded to the metal core of the organometallic compound, a hydrogen atom (H) may be dissociated from the —P(═O)(OH)₂ group in General Formula 1, and thus, the —P(═O)(OH)₂ group may become —P(═O)(OH)O— or —P(═O)(O—)₂. Therefore, a ligand represented by R¹—P(═O)(OH)O— or R¹—P(═O)(O—)₂ may be derived from the compound represented by General Formula 1.

In some embodiments, in General Formula 1, R¹ may be a substituted or unsubstituted C1 to C30 linear alkyl group, a substituted or unsubstituted C1 to C30 branched alkyl group, a substituted or unsubstituted C2 to C30 alkenyl group, or a substituted or unsubstituted C2 to C30 alkynyl group.

In some embodiments, in General Formula 1, R¹ may be a substituted or unsubstituted C3 to C30 cycloalkyl group, a substituted or unsubstituted C6 to C30 aryl group, a substituted or unsubstituted C2 to C30 heteroaryl group, or a substituted or unsubstituted C7 to C30 alkylaryl group.

In some embodiments, the at least one first organic ligand precursor represented by General Formula 1 may include an alkyl phosphonic acid, a halogenated alkyl phosphonic acid, or a combination thereof.

In some embodiments, the at least one first organic ligand precursor may include a cycloalkyl phosphonic acid, a halogenated cycloalkyl phosphonic acid, an aromatic phosphonic acid, a halogenated aromatic phosphonic acid, an alkyl aromatic phosphonic acid, a halogenated alkyl aromatic phosphonic acid, an araliphatic phosphonic acid, a halogenated araliphatic phosphonic acid, an alicyclic phosphonic acid, or any combination thereof.

For example, the at least one first organic ligand precursor may include methylphosphonic acid, 2-chloroethylphosphonic acid, n-butylphosphonic acid, n-octylphosphonic acid, 11-hydroxyundecylphosphonic acid, octadecylphosphonic acid, (11-phosphonoundecyl)phosphonic acid, (3,3,4,4,5,5,6,6,7,7,8,8,8-tridecafluorooctyl)phosphonic acid, benzylphosphonic acid, phenylphosphonic acid, benzene-1,3,5-triyltris(phosphonic acid), aminomethylphosphonic acid, 2-aminoethylphosphonic acid, 2,3,4,5,6-pentafluorobenzylphosphonic acid, 2,4-diethyl-3,6-dihydroxyphenylphosphonic acid, 3,4,4,5,5,6,6,6-fluorohexylphosphonic acid, 2-[2-(2-methoxyethoxy)ethoxy]ethylphosphonic acid, [3-(4-{[4′-(phenyl-w-tolylamino)biphenyl-4-yl]-m-tolylamino}phenoxy)propyl]-phosphonic acid, (11-prop-2-ynyloxyundecyl)phosphonic acid, (11-acryloyloxyundecyl)phosphonic acid, (11-cinnamoyloxyundecyl)phosphonic acid, 3-(9H-carbazol-9-yl)propylphosphonic acid, 3-(3,6-di-tert-butyl-9H-carbazol-9-yl)propylphosphonic acid, pentabromobenzylphosphonic acid, or any combination thereof.

In some embodiments, in the photoresist composition according to some embodiments, the at least one first organic ligand precursor may include only a single first organic ligand precursor or may include at least two, for example, two, three, or four, first organic ligand precursors. For example, in the photoresist composition according to some embodiments, the at least one first organic ligand precursor may include at least one (e.g., 1, 2, 3 or more) first organic ligand precursor selected from the following structures, but the inventive concept is not limited to the following compounds shown as examples below.

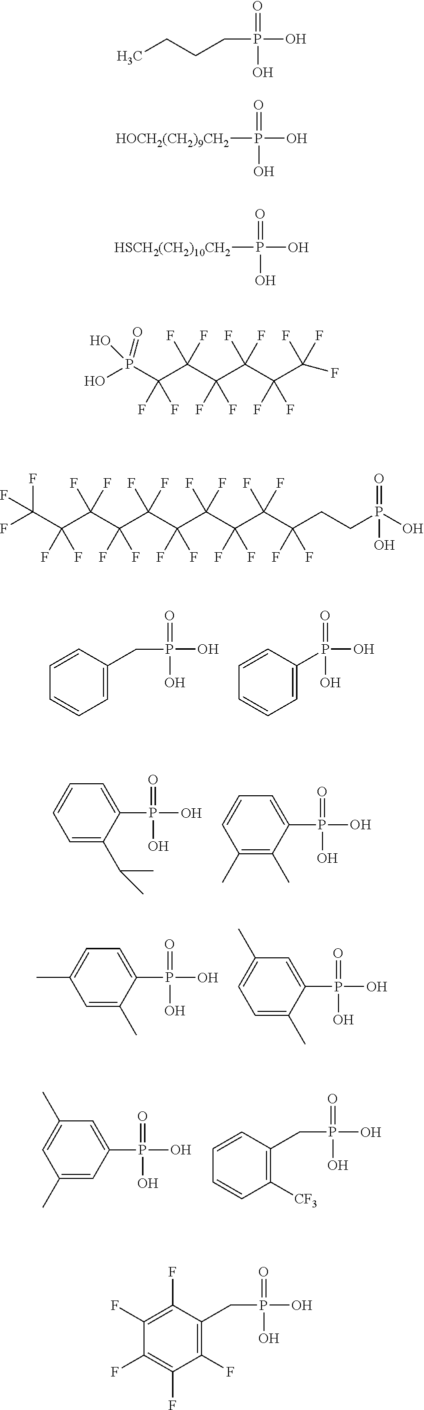

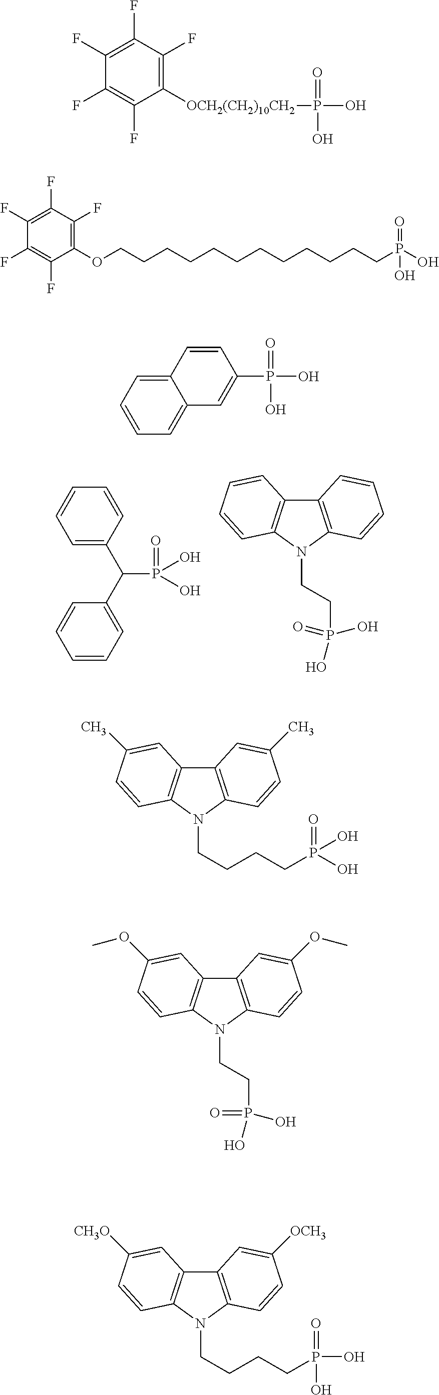

In some embodiments, in the photoresist composition according to some embodiments, a molar ratio of the at least one first organic ligand precursor to the organometallic compound may be selected from a range of about 0.01 to about 10, e.g., about 0.01 to about 5, about 0.01 to about 2.5, about 0.01 to about 1, about 0.01 to about 0.5, about 0.01 to about 0.25, about 0.01 to about 0.1, about 0.01 to about 0.075, about 0.01 to about 0.05, or about 0.02 to about 0.04. For example, in the photoresist composition according to some embodiments, the molar ratio of the at least one first organic ligand precursor to the organometallic compound may be in a range of about 0.02 to about 0.04.

In some embodiments, the photoresist composition according to some embodiments may further include at least one second organic ligand precursor including an organic carboxylic acid compound and being represented by General Formula 2.

R²—COOH [General Formula 2]

In General Formula 2, R² may be an aliphatic hydrocarbon group or an aromatic hydrocarbon group selected from a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 alkylaryl group, and a substituted or unsubstituted C7 to C30 arylalkyl group.

In General Formula 2, when R² has a substituted hydrocarbon group, all or some hydrogen atoms, which are included in the hydrocarbon group of R², may independently be substituted with a halogen atom, a hydroxyl group, a sulfonic acid group, an amino group, or a thiol (—SH) group to thereby provide the substituted hydrocarbon group.

The at least one second organic ligand precursor, which is included in the photoresist composition according to some embodiments, may have a structure capable of forming (e.g., that can and/or is configured to form) a coordination complex with the metal core of the organometallic compound. When the at least one second organic ligand precursor forms a coordination complex with the metal core of the organometallic compound, the at least one second organic ligand precursor may have a structure having at least one binding site for the metal core of the organometallic compound. When the at least one second organic ligand precursor forms a coordination complex with the metal core, the at least one second organic ligand precursor may have a structure having one or more binding sites for the metal core. In some embodiments, the compound represented by General Formula 2 may be a compound capable of being (e.g., that can be and/or is configured to be) coordination-bonded to the metal core. When the compound represented by General Formula 2 is coordination-bonded to the metal core of the organometallic compound, a hydrogen atom (H) may be dissociated from the —COOH group in General Formula 2, and thus, the —COOH group may become —C(═O)O—. Therefore, a ligand represented by R²—C(═O)O— may be derived from the compound represented by General Formula 2.

In some embodiments, in General Formula 2, R² may be, but is not limited to, a methyl group, an ethyl group, an n-propyl group, an isopropyl group, an n-butyl group, an isobutyl group, a sec-butyl group, a tert-butyl group, a fluoromethyl group, a difluoromethyl group, a trifluoromethyl group, a chloromethyl group, a dichloromethyl group, a trichloromethyl group, a bromomethyl group, a dibromomethyl group, a tribromomethyl group, an iodomethyl group, a diiodomethyl group, a triiodomethyl group, a trifluoroethyl group, a trichloroethyl group, a tribromoethyl group, a pentafluoroethyl group, a pentachloroethyl group, a pentabromoethyl group, a heptafluoropropyl group, a heptachloropropyl group, a nonafluorobutyl group, a nonachlorobutyl group, a nonabromobutyl group, a nonaiodobutyl group, a methoxy group, an ethoxy group, an n-propoxy group, an isopropoxy group, an n-butoxy group, an isobutoxy group, a sec-butoxy group, or a tert-butoxy group.

In some embodiments, the at least one second organic ligand precursor may be selected from, but is not limited to, acetic acid, propionic acid, butyric acid, isobutyric acid, pivalic acid, valeric acid, caproic acid, benzoic acid, and any combination thereof.

In some embodiments, in the photoresist composition according to some embodiments, the at least one second organic ligand precursor may include only a single second organic ligand precursor or may include at least two, for example, two, three, or four, second organic ligand precursors. For example, in the photoresist composition according to some embodiments, the at least one second organic ligand precursor may include at least one second organic ligand precursor selected from the compounds set forth above as examples, but the inventive concept is not limited to the compounds set forth above.

In some embodiments, in the photoresist composition according to some embodiments, a molar ratio of the at least one second organic ligand precursor to the organometallic compound may be selected from a range of about 0.01 to about 10, e.g., about 0.01 to about 5, about 0.01 to about 2.5, about 0.01 to about 1, about 0.01 to about 0.5, about 0.01 to about 0.25, about 0.01 to about 0.1, about 0.01 to about 0.075, about 0.01 to about 0.05, about 0.5 to about 1.5, about 0.75 to about 1.25, about 0.85 to about 1.15, about 0.9 to about 1.1, or about 0.95 to about 1.05. For example, in the photoresist composition according to some embodiments, the molar ratio of the at least one second organic ligand precursor to the organometallic compound may be in a range of about 0.9 to about 1.1.

In some embodiments, when the photoresist composition according to some embodiments includes the at least one first organic ligand precursor and the at least one second organic ligand precursor, the molar ratio of the at least one first organic ligand precursor to the organometallic compound may be less than, greater than, or equal to the molar ratio of the at least one second organic ligand precursor to the organometallic compound, in the photoresist composition.

In the photoresist composition according to some embodiments, the organometallic compound may be represented by General Formula 3.

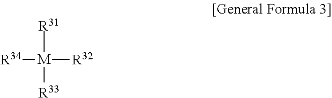

wherein, in General Formula 3,
M may be Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe, and
R³¹, R³², R³³, and R³⁴ may each independently be a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, a —R³⁵—O—R³⁶ group (where R³⁵ is a substituted or unsubstituted C1 to C20 alkylene group and R³⁶ is a substituted or unsubstituted C1 to C20 alkyl group), an R³⁷—COO— group, an R³⁷—SO₃— group, or an R³⁷—SO₂— group when R³⁷ is a substituted or unsubstituted C1 to C10 alkyl group or a substituted or unsubstituted phenyl group.

In General Formula 3, R³¹, R³², R³³, and R³⁴ may each independently include a hydrocarbyl group substituted with at least one heteroatom functional group, the heteroatom functional group including an oxygen atom, a nitrogen atom, a halogen element, a cyano group, a thio group, a silyl group, an ether group, a carbonyl group, an ester group, a nitro group, an amino group, or a combination thereof. The halogen element may be F, Cl, Br, or I.

In some embodiments, in General Formula 3, R³¹, R³², R³³, and R³⁴ may each independently include a methyl group, an ethyl group, a propyl group, a butyl group, an isopropyl group, a tert-butyl group, a tert-amyl group, a sec-butyl group, a cyclopropyl group, a cyclobutyl group, a cyclopentyl group, or a cyclohexyl group.

In some embodiments, in General Formula 3, R³¹, R³², R³³, and R³⁴ may each independently include an acid group selected from a hydroxyl group, a sulfonate group, a carboxyl group, and a phosphonate group.

In some embodiments, an organic ligand represented by General Formula 1 may include a CF₃COO— ligand, a CF₃SO₃— ligand, a CF₂CF₂SO₃— ligand, a CF₃CF₂(CF₃)₂CO— ligand, a CF₃SO₂-ligand, a p-toluenesulfonyl ligand, or a diethyl phosphate ligand.

In some embodiments, in General Formula 3, R³¹, R³², R³³, and R³⁴ may each independently include an aromatic ring, a heteroaromatic ring, or any combination thereof. The aromatic ring may include a single aromatic ring, such as benzene; a heteroaryl group, such as pyridine, pyrimidine, or thiophene; a condensed aryl group, such as quinoline, isoquinoline, naphthalene, anthracene, or phenanthrene; or the like. The heteroaryl group and the condensed aryl group may each independently include at least one heteroatom selected from an O atom, an S atom, and an N atom.

In some embodiments, in General Formula 3, R³¹, R³², R³³, and R³⁴ may each independently include at least one selected from the following structural units, wherein in the following structural units, * represents a binding site.

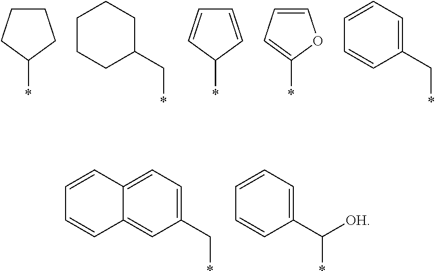

In some embodiments, in General Formula 3, R³¹, R³², R³³, and R³⁴ may each independently include at least one selected from the following structural units.

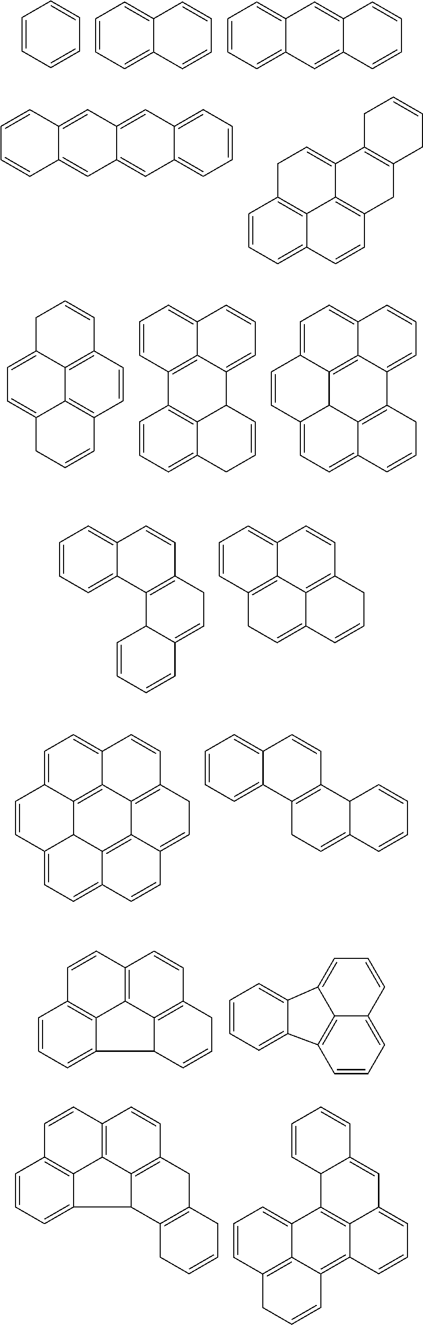

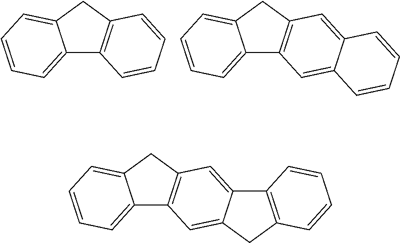

In some embodiments, the organometallic compound may include a plurality of organic ligands, and each of the plurality of organic ligands may independently include a monodentate ligand.

In some embodiments, in General Formula 3, two or more (e.g., 2, 3, or 4) of R³¹, R³², R³³, and R³⁴ may have the same structure. For example, in General Formula 3, two or three ligands selected from R³¹, R³², R³³, and R³⁴ may have the same chemical structure. In some embodiments, in General Formula 3, at least two ligands selected from R³¹, R³², R³³, and R³⁴ may have different chemical structures from each other.

In some embodiments, the organometallic compound may include a polydentate ligand. The polydentate ligand may include, but is not limited to, a bidentate ligand including two coordinatable atoms, a tridentate ligand including three coordinatable atoms, or a tetradentate ligand including four coordinatable atoms. For example, the polydentate ligand may include, but is not limited to, a structure selected from quinoline, β-diketonate, ethylenediaminetetraacetic acid (EDTA), 2,2′-bis(diphenylphosphino)-1,1′-binaphthyl (BINAP), salen (2,2′-ethylenebis(nitrilomethylidene)diphenol), norbornene dicarboxylic acid, camphoric acid, and derivatives thereof.

In some embodiments, one organic ligand selected from the plurality of organic ligands, that is, R³¹, R³², R³³, and R³⁴, in General Formula 3, may be a hydrocarbon group, and the other organic ligands of the plurality of organic ligands may each independently be an R³⁷COO— group (wherein each R³⁷ is a substituted or unsubstituted C1 to C10 alkyl group or a substituted or unsubstituted phenyl group). For example, in General Formula 3, R³¹ may be a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a —R³⁵—O—R³⁶ group (where R³⁵ is a substituted or unsubstituted C1 to C20 alkylene group and R³⁶ is a substituted or unsubstituted C1 to C20 alkyl group), and R³², R³³, and R³⁴ may each independently be an R³⁷—COO— group (wherein each R³⁷ is a substituted or unsubstituted C1 to C10 alkyl group or a substituted or unsubstituted phenyl group).

In the photoresist composition according to some embodiments, the metal core may be present in an amount of about 0.1% by weight (wt %) to about 5 wt % based on the total weight of the photoresist composition, for example, about 0.1 wt % to about 5 wt %, about 0.1 wt % to about 4 wt %, about 0.1 wt % to about 3 wt %, about 0.1 wt % to about 2 wt %, about 0.1 wt % to about 1 wt %, about 0.1 wt % to about 0.5 wt %, about 0.5 wt % to about 5 wt %, about 0.5 wt % to about 4 wt %, about 0.5 wt % to about 3 wt %, about 0.5 wt % to about 3 wt %, about 0.5 wt % to about 1 wt %, about 1 wt % to about 5 wt %, about 1 wt % to about 4 wt %, about 1 wt % to about 3 wt %, or about 1 wt % to about 2 wt %, but the inventive concept is not limited thereto.

The organometallic compound in the photoresist composition according to some embodiments may be commercially available or may be obtained from a well-known precursor through synthesis by a method publicly known to those of ordinary skill in the art.

In some embodiments, the photoresist composition according to some embodiments may further include a photoinitiator. The photoinitiator may be configured to generate acids or radicals due to light. After a photoresist film obtained from the photoresist composition is exposed to light, the photoinitiator may generate acids or radicals by absorbing light (e.g., light comprising a wavelength of about 13.5 nm) in an exposed region of the photoresist film. The acids or the radicals generated from photoinitiator may react with an organic ligand of the organometallic compound and thus induce a dissociation reaction of the organic ligand. Therefore, when the photoinitiator is included in the photoresist composition according to some embodiments, an organic ligand may be dissociated from the organometallic compound by the acids or the radicals generated from the photoinitiator, and after the organic ligand is dissociated, a hydroxyl (—OH) functional group may be generated at a site from which the organic ligand is dissociated in the organometallic compound. A condensation reaction of the hydroxyl (—OH) functional group may be induced by a bake process that is subsequent to the exposure process of the photoresist film, and as a result, a network (hereinafter, referred to as a “metal structure network”), which includes a cross-linked structure (for example, an M-O-M cross-linked structure) including a plurality of metals (M), may be formed (e.g., densely formed).

In some embodiments, where the photoinitiator is included in the photoresist composition according to some embodiments, the photoinitiator may supplement the relatively low reactivity of the organometallic compound when a photoresist film obtained from the photoresist composition is exposed to light, and the photosensitivity in an exposed region of the photoresist film may be adjusted depending on the amount of the photoinitiator. In particular, the photoinitiator may accelerate a ligand dissociation reaction in the organometallic compound by using acids or radicals in the exposed region of the photoresist film, thereby inducing a photoreaction to be limitedly performed only in the exposed region of the photoresist film.

The photoinitiator may include a photoacid generator (PAG) configured to generate an acid by light, a photoradical generator (PRG) configured to generate a radical by light, or a combination of a PAG and a PRG.

The PAG may generate an acid when exposed to light of one selected from a KrF excimer laser (248 nm), an ArF excimer laser (193 nm), an F₂ excimer laser (157 nm), and an EUV laser (13.5 nm). In some embodiments, the PAG may include triarylsulfonium salts, diaryliodonium salts, sulfonates, or mixtures thereof. For example, the PAG may include, but is not limited to, triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonate, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or a mixture thereof.

When the PRG is exposed to light of one selected from a KrF excimer laser (248 nm), an ArF excimer laser (193 nm), an F₂ excimer laser (157 nm), and an EUV laser (13.5 nm), the PRG may absorb the light and generate a radical, thereby starting the polymerization of the organometallic compound of the photoresist composition according to some embodiments. In some embodiments, the PRG may include an acylphosphine oxide-based compound, an oxime ester-based compound, or the like.

The acylphosphine oxide-based compound may include, for example, 2,4,6-trimethylbenzoyl-diphenylphosphine oxide, bis(2,4,6-trimethylbenzoyl)-phenylphosphine oxide, bis(2,6-dimethoxybenzoyl)-(2,4,4-trimethylpentyl)phosphine oxide, or the like.

The oxime ester-based compound may include, for example, 1-phenylpropane-1,2-dione-2-(O-ethoxycarbonyl)oxime, 1-phenylbutane-1,2-dione-2-(O-methoxycarbonyl)oxime, 1,3-diphenylpropane-1,2,3-trione-2-(O-ethoxycarbonyl)oxime, 1-[4-(phenylthio)phenyl]octane-1,2-dione-2-(O-benzoyl)oxime, 1-[4-[4-(carboxyphenyl)thio]phenyl]propane-1,2-dione-2-(O-acetyl)oxime, 1-[9-ethyl-6-(2-methylbenzoyl)-9H-carbazol-3-yl]ethanone-1-(O-acetyl)oxime, 1-[9-ethyl-6-[2-methyl-4-[1-(2,2-dimethyl-1,3-dioxolane-4-yl)methyloxy]benzoyl]-9H-carbazol-3-yl] ethanone-1-(O-acetyl)oxime, or the like.

In some embodiments, the PRG may include a commercially available product, such as IRGACURE 651, IRGACURE 184, IRGACURE 1173, IRGACURE 2959, IRGACURE 127, IRGACURE 907, IRGACURE 369, IRGACURE 379, IRGACURE TPO, IRGACURE 819, IRGACURE OXE01, IRGACURE OXE02, IRGACURE MBF, or IRGACURE 754 (which is a product model of BASF Co., Ltd.).

The photoresist composition according to the inventive concept may not include the photoinitiator. In some embodiments, the photoresist composition according to the inventive concept may include, as the photoinitiator, a single material selected from the PAGs and the PRGs set forth above, or may include, as the photoinitiator, at least two materials selected from the PAGs and the PRGs set forth above. When the photoinitiator is included in the photoresist composition according to some embodiments, the photoinitiator may be present in an amount of about 2 mol % to about 60 mol %, e.g., about 2 mol % to about 60 mol %, about 2 mol % to about 50 mol %, about 2 mol % to about 40 mol %, about 2 mol % to about 30 mol %, about 2 mol % to about 20 mol %, about 2 mol % to about 10 mol %, about 2 mol % to about 5 mol %, or about 2 mol % to about 60 mol %, about 5 mol % to about 50 mol %, about 5 mol % to about 40 mol %, about 5 mol % to about 30 mol %, about 5 mol % to about 20 mol %, about 5 mol % to about 10 mol %, about 10 mol % to about 60 mol %, about 10 mol % to about 50 mol %, about 10 mol % to about 40 mol %, about 10 mol % to about 30 mol %, or about 10 mol % to about 20 mol %, based on the total amount of the organometallic compound, but the inventive concept is not limited thereto.

The solvent in the photoresist composition may include an organic solvent. The organic solvent may include, but is not limited to, at least one of ethers, alcohols, glycol ethers, aromatic hydrocarbon compounds, ketones, and esters. For example, the organic solvent may include ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbon: MIBC), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxyethoxy propionate, ethoxyethoxy propionate, or any combination thereof.

In the photoresist composition according to some embodiments, the solvent may comprise the remaining balance of the photoresist composition, e.g., comprise the balance except for amounts of main components including the organometallic compound, the at least one first organic ligand precursor, the at least one second organic ligand precursor, and/or the photoinitiator. In some embodiments, the solvent may be present in an amount of about 0.1 wt % to about 99.8 wt % based on the total weight of the photoresist composition, e.g., 0.1 wt %, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33 wt %, 34 wt %, 35 wt %, 36 wt %, 37 wt %, 38 wt %, 39 wt %, 40 wt %, 41 wt %, 42 wt %, 43 wt %, 44 wt %, 45 wt %, 46 wt %, 47 wt %, 48 wt %, 49 wt %, 50 wt %, 51 wt %, 52 wt %, 53 wt %, 54 wt %, 55 wt %, 56 wt %, 57 wt %, 58 wt %, 59 wt %, 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, 90 wt %, 91 wt %, 92 wt %, 93 wt %, 94 wt %, 95 wt %, 96 wt %, 97 wt %, 98 wt %, 99 wt %, 99.1 wt %, 99.2 wt %, 99.3 wt %, 99.4 wt %, 99.5 wt %, 99.6 wt %, 99.7 wt %, or 99.8 wt %, or between about 0.1 wt % and 98 wt %, between about 0.1 wt % and 75 wt %, between about 0.1 wt % and 60 wt %, between about 0.1 wt % and 40 wt %, between about 5 wt % and 98 wt %, between about 40 wt % and 99.8 wt %, between about 40 wt % and 98 wt %, between about 35 wt % and 98 wt %, between about 20 wt % and 98 wt %, or between about between about 10 wt % and 98 wt % based on the total weight of the photoresist composition, but the inventive concept is not limited thereto.

In some embodiments, when the photoresist composition according to some embodiments includes the PAG as the photoinitiator, the photoresist composition may further include a basic quencher. The basic quencher may include a compound capable of trapping an acid in a non-exposed region of a photoresist film, when the acid generated from the PAG of the photoresist composition according to some embodiments or the acid generated from another photo-decomposable compound diffuses into the non-exposed region. The photoresist composition according to some embodiments includes the basic quencher, thereby suppressing the diffusion rate of an acid in the photoresist film obtained from the photoresist composition.

In some embodiments, the basic quencher may include primary aliphatic amines, secondary aliphatic amines, tertiary aliphatic amines, aromatic amines, heteroaromatic ring-containing amines, nitrogen-containing compounds having carboxyl groups, nitrogen-containing compounds having sulfonyl groups, nitrogen-containing compounds having hydroxyl groups, nitrogen-containing compounds having hydroxyphenyl groups, alcoholic nitrogen-containing compounds, amides, imides, carbamates, or ammonium salts. For example, the basic quencher may include, but is not limited to, triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl)aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or any combination thereof.

In some embodiments, the basic quencher may include a photobase generator. The photobase generator may generate a base by absorbing active energy rays through light irradiation and thus undergoing the decomposition of a chemical structure thereof. Accordingly, when a certain region of a photoresist film formed from the photoresist composition, which includes the basic quencher including the photobase generator, is exposed to light, the sensitivity in the exposed region may be adjusted by trapping an acid by the photobase generator in the exposed region of the photoresist film and an acid may be suppressed from diffusing from the exposed region into a non-exposed region. Therefore, a metal structure network, which includes a metal oxide including the metal core, may be selectively formed only in the exposed region of the photoresist film, and adverse effects due to unintended diffusion of the acid, such as the deterioration of critical dimension (CD) distribution in an edge of a photoresist pattern obtained after a development process, may be prevented.

A material constituting the photobase generator is not particularly limited so long as the material generates a base due to light irradiation. In some embodiments, the photobase generator may include a nonionic photobase generator. In some embodiments, the photobase generator may include an ionic photobase generator.

In some embodiments, the photobase generator may include a carboxylate or sulfonate salt of a photo-decomposable cation. For example, the photo-decomposable cation of the photobase generator may include a sulfonium cation. The sulfonium cation may include a substituted or unsubstituted C1 to C12 alkyl group, a substituted or unsubstituted C3 to C12 cycloalkyl group, a C6 to C30 aryl group, or a C2 to C30 heteroaryl group. The alkyl group, the cycloalkyl group, the aryl group, and the heteroaryl group may each include at least one heteroatom selected from an O atom, an S atom, and an N atom. For example, the sulfonium cation may include, but is not limited to, a phenyl group, a cyclopentyl group, a cyclohexyl group, an adamantyl group, a methyl group, an ethyl group, a propyl group, a butyl group, a t-butyl group, or an isopropyl group.

The photo-decomposable cation of the photobase generator may form a complex with an anion of a C1 to C20 carboxylic acid. The carboxylic acid may include, but is not limited to, formic acid, acetic acid, propionic acid, tartaric acid, succinic acid, cyclohexanecarboxylic acid, benzoic acid, or salicylic acid.

In some embodiments, the photobase generator may include, but is not limited to, triphenylsulfonium heptafluorobutyric acid or triphenyl sulfonium hexafluoroantimonate (TPS-SbF6).

In the photoresist composition according to the inventive concept, the basic quencher may be used alone, or a mixture of at least two basic quenchers may be used. The basic quencher may be present in an amount of about 0 mol % to about 50 mol %, e.g., 0 mol %, 1 mol %, 2 mol %, 3 mol %, 4 mol %, 5 mol %, 6 mol %, 7 mol %, 8 mol %, 9 mol %, 10 mol %, 11 mol %, 12 mol %, 13 mol %, 14 mol %, 15 mol %, 16 mol %, 17 mol %, 18 mol %, 19 mol %, 20 mol %, 21 mol %, 22 mol %, 23 mol %, 24 mol %, 25 mol %, 26 mol %, 27 mol %, 28 mol %, 29 mol %, 30 mol %, 31 mol %, 32 mol %, 33 mol %, 34 mol %, 35 mol %, 36 mol %, 37 mol %, 38 mol %, 39 mol %, 40 mol %, 41 mol %, 42 mol %, 43 mol %, 44 mol %, 45 mol %, 46 mol %, 47 mol %, 48 mol %, 49 mol %, or 50 mol %, based on the total weight of the organometallic compound, but the inventive concept is not limited thereto.

In some embodiments, when the photoresist composition according to some embodiments includes the PRG as the photoinitiator, the photoresist composition may further include a radical quencher capable of trapping a radical.

In some embodiments, the radical quencher may include a quinone-type free radical or a nitroxide (IUPAC name: aminoxyl) free radical.

The quinone-type free radical may include, but is not limited to, p-benzoquinone, hydroquinone (1,4-dihydroxybenzene), hydroquinone monomethyl ether (4-methoxyphenol), hydroquinone monophenyl ether, mono-t-butyl hydroquinone (MTBHQ), di-t-butyl hydroquinone, di-t-amyl hydroquinone, toluhydroquinone, p-benzoquinone dioxime, 2,6-dichloro-1,4-benzoquinone, 2,3,5,6-tetramethyl-1,4-benzoquinone, 2,5-dichloro-3,6-dihydroxy-p-benzoquinone, methyl-p-benzoquinone, 6-anilinoquinoline-5,8-quinone, pyrroloquinoline quinone, 2-allyl-6-methoxybenzo-1,4-quinone, or any combination thereof.

The nitroxide free radical may include, but is not limited to, di-tert-butyl nitroxide (DTBN), 2,2,6,6-tetramethyl-1-peperidine 1-oxyl (TEMPO), oxo TEMPO (4-oxo-2,2,6,6-tetramethyl-1-peperidine 1-oxyl), 1,1,3,3-tetraethylisoindolin-N-oxyl, N-tert-butyl-N-[1-(diethoxyphosphoryl)-2,2-dimethylpropyl]aminoxyl (SG1), (N-tert-butyl-N-(2-methyl-1-phenylpropyl) aminoxyl (TIPNO), or any combination thereof.

In some embodiments, when a photolithography process is performed using the photoresist composition according to the inventive concept, because a radical generated from the PRG in an exposed region of a photoresist film obtained from the photoresist composition is quenched by the radical quencher, the sensitivity in the exposed region may be adjusted and a radical introduced from the exposed region into a non-exposed region may be quenched by the radical quencher.

Therefore, a network, which includes a metal oxide including the metal core of the organometallic compound, may be selectively formed only in the exposed region, and adverse effects due to unintended diffusion of the radical, such as the deterioration of CD distribution in an edge of a photoresist pattern obtained after a development process, may be prevented.

In the photoresist composition according to the inventive concept, the radical quencher may be used alone, or a mixture of at least two radical quenchers may be used. The radical quencher may be present in an amount of about 0 mol % to about 50 mol %, e.g., 0 mol %, 1 mol %, 2 mol %, 3 mol %, 4 mol %, 5 mol %, 6 mol %, 7 mol %, 8 mol %, 9 mol %, 10 mol %, 11 mol %, 12 mol %, 13 mol %, 14 mol %, 15 mol %, 16 mol %, 17 mol %, 18 mol %, 19 mol %, 20 mol %, 21 mol %, 22 mol %, 23 mol %, 24 mol %, 25 mol %, 26 mol %, 27 mol %, 28 mol %, 29 mol %, 30 mol %, 31 mol %, 32 mol %, 33 mol %, 34 mol %, 35 mol %, 36 mol %, 37 mol %, 38 mol %, 39 mol %, 40 mol %, 41 mol %, 42 mol %, 43 mol %, 44 mol %, 45 mol %, 46 mol %, 47 mol %, 48 mol %, 49 mol %, or 50 mol %, based on the total weight of the organometallic compound, but the inventive concept is not limited thereto.

In some embodiments, the photoresist composition according to some embodiments may further include at least one selected from a leveling agent, a surfactant, a dispersant, a moisture absorbent, and a coupling agent.

The leveling agent is for improving coating flatness when the photoresist composition is coated on a substrate, and a commercially available leveling agent publicly known in the art may be used.

The surfactant may improve the coating uniformity and wettability of the photoresist composition. In some embodiments, the surfactant may include, but is not limited to, a sulfuric acid ester salt, a sulfonic acid salt, phosphoric acid ester, soap, an amine salt, a quaternary ammonium salt, polyethylene glycol, an alkylphenol ethylene oxide adduct, a polyhydric alcohol, a nitrogen-containing vinyl polymer, or any combination thereof. For example, the surfactant may include an alkylbenzene sulfonate, an alkyl pyridinium salt, polyethylene glycol, or a quaternary ammonium salt. When the photoresist composition includes the surfactant, the surfactant may be present in an amount of about 0.001 wt % to about 3 wt % based on the total weight of the photoresist composition, e.g., about 0.001 wt % to about 3 wt %, about 0.001 wt % to about 2 wt %, about 0.001 wt % to about 1 wt %, about 0.001 wt % to about 0.1 wt %, about 0.001 wt % to about 0.05 wt %, about 0.001 wt % to about 0.01 wt %, about 0.01 wt % to about 3 wt %, about 0.01 wt % to about 2 wt %, about 0.1 wt % to about 1 wt %, about 0.01 wt % to about 0.5 wt %, about 0.1 wt % to about 3 wt %, about 0.1 wt % to about 2 wt %, about 0.1 wt % to about 1 wt %, or about 0.1 wt % to about 0.5 wt % based on the total weight of the photoresist composition.

The dispersant may cause the respective components constituting the photoresist composition to be uniformly dispersed in the photoresist composition. In some embodiments, the dispersant may include, but is not limited to, an epoxy resin, polyvinyl alcohol, polyvinyl butyral, polyvinylpyrrolidone, glucose, sodium dodecyl sulfate, sodium citrate, oleic acid, linoleic acid, or any combination thereof. When the photoresist composition includes the dispersant, the dispersant may be present in an amount of about 0.001 wt % to about 5 wt % based on the total weight of the photoresist composition, e.g., about 0.001 wt % to about 5 wt %, about 0.001 wt % to about 4 wt %, about 0.001 wt % to about 3 wt %, about 0.001 wt % to about 2 wt %, about 0.001 wt % to about 1 wt %, about 0.001 wt % to about 0.1 wt %, about 0.01 wt % to about 5 wt %, about 0.01 wt % to about 4 wt %, about 0.1 wt % to about 3 wt %, about 0.01 wt % to about 2 wt %, about 0.01 wt % to about 1 wt %, about 0.1 wt % to about 5 wt %, about 0.1 wt % to about 4 wt %, about 0.1 wt % to about 3 wt %, about 0.1 wt % to about 2 wt %, about 0.1 wt % to about 1 wt %, about 0.1 wt % to about 0.5 wt %, about 0.5 wt % to about 5 wt %, about 0.5 wt % to about 4 wt %, about 0.5 wt % to about 3 wt %, about 0.5 wt % to about 2 wt %, about 0.5 wt % to about 1 wt %, about 1 wt % to about 5 wt %, about 2 wt % to about 5 wt %, about 0.05 wt % to about 2 wt %, about 0.05 wt % to about 1.5 wt %, about 0.05 wt % to about 1 wt %, or about 0.05 wt % to about 0.5 wt % based on the total weight of the photoresist composition.

The moisture absorbent may prevent adverse effects due to water in the photoresist composition. In some embodiments, the moisture absorbent may include, but is not limited to, polyoxyethylene nonylphenol ether, polyethylene glycol, polypropylene glycol, polyacrylamide, or any combination thereof. When the photoresist composition includes the moisture absorbent, the moisture absorbent may be present in an amount of about 0.001 wt % to about 10 wt % based on the total weight of the photoresist composition, e.g., about 0.001 wt % to about 10 wt %, about 0.001 wt % to about 9 wt %, about 0.001 wt % to about 8 wt %, about 0.001 wt % to about 7 wt %, about 0.001 wt % to about 6 wt %, about 0.001 wt % to about 5 wt %, about 0.001 wt % to about 4 wt %, about 0.001 wt % to about 3 wt %, about 0.001 wt % to about 2 wt %, about 0.001 wt % to about 1 wt %, about 0.001 wt % to about 0.1 wt %, about 0.01 wt % to about 10 wt %, about 0.01 wt % to about 9 wt %, about 0.01 wt % to about 8 wt %, about 0.01 wt % to about 7 wt %, about 0.01 wt % to about 6 wt %, about 0.01 wt % to about 5 wt %, about 0.01 wt % to about 4 wt %, about 0.1 wt % to about 3 wt %, about 0.01 wt % to about 2 wt %, about 0.01 wt % to about 1 wt %, about 0.1 wt % to about 10 wt %, about 0.1 wt % to about 9 wt %, about 0.1 wt % to about 8 wt %, about 0.1 wt % to about 7 wt %, about 0.1 wt % to about 6 wt %, about 0.1 wt % to about 5 wt %, about 0.1 wt % to about 4 wt %, about 0.1 wt % to about 3 wt %, about 0.1 wt % to about 2 wt %, about 0.1 wt % to about 1 wt %, about 0.1 wt % to about 0.5 wt %, about 0.5 wt % to about 10 wt %, about 0.5 wt % to about 9 wt %, about 0.5 wt % to about 8 wt %, about 0.5 wt % to about 7 wt %, about 0.5 wt % to about 6 wt %, about 0.5 wt % to about 5 wt %, about 0.5 wt % to about 4 wt %, about 0.5 wt % to about 3 wt %, about 0.5 wt % to about 2 wt %, about 0.5 wt % to about 1 wt %, about 1 wt % to about 10 wt %, about 1 wt % to about 9 wt %, about 1 wt % to about 8 wt %, about 1 wt % to about 7 wt %, about 1 wt % to about 6 wt %, about 1 wt % to about 5 wt %, about 1 wt % to about 4 wt %, about 1 wt % to about 3 wt %, about 1 wt % to about 2 wt %, about 2 wt % to about 5 wt %, about 2 wt % to about 10 wt %, about 5 wt % to about 10 wt %, about 0.05 wt % to about 2 wt %, about 0.05 wt % to about 1.5 wt %, about 0.05 wt % to about 1 wt %, or about 0.05 wt % to about 0.5 wt % based on the total weight of the photoresist composition.

The coupling agent may improve adhesion to a lower film when the photoresist composition is coated on the lower film. In some embodiments, the coupling agent may include a silane coupling agent. The silane coupling agent may include, but is not limited to, vinyltrimethoxysilane, vinyltriethoxysilane, vinyltrichlorosilane, vinyltris(p-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy[3-(phenylamino)propyl]silane. When the photoresist composition includes the coupling agent, the coupling agent may be present in an amount of about 0.001 wt % to about 5 wt % based on the total weight of the photoresist composition, e.g., about 0.001 wt % to about 5 wt %, about 0.001 wt % to about 4 wt %, about 0.001 wt % to about 3 wt %, about 0.001 wt % to about 2 wt %, about 0.001 wt % to about 1 wt %, about 0.001 wt % to about 0.1 wt %, about 0.01 wt % to about 5 wt %, about 0.01 wt % to about 4 wt %, about 0.1 wt % to about 3 wt %, about 0.01 wt % to about 2 wt %, about 0.01 wt % to about 1 wt %, about 0.1 wt % to about 5 wt %, about 0.1 wt % to about 4 wt %, about 0.1 wt % to about 3 wt %, about 0.1 wt % to about 2 wt %, about 0.1 wt % to about 1 wt %, about 0.1 wt % to about 0.5 wt %, about 0.5 wt % to about 5 wt %, about 0.5 wt % to about 4 wt %, about 0.5 wt % to about 3 wt %, about 0.5 wt % to about 2 wt %, about 0.5 wt % to about 1 wt %, about 1 wt % to about 5 wt %, about 2 wt % to about 5 wt %, about 0.05 wt % to about 2 wt %, about 0.05 wt % to about 1.5 wt %, about 0.05 wt % to about 1 wt %, or about 0.05 wt % to about 0.5 wt % based on the total weight of the photoresist composition.

In the photoresist composition according to some embodiments, when the solvent includes only an organic solvent, the photoresist composition may further include water. In this case, water may be present in an amount of about 0.001 wt % to about 0.1 wt % in the photoresist composition, e.g., about 0.001 wt % to about 0.1 wt %, about 0.001 wt % to about 0.01 wt %, about 0.01 wt % to about 0.05 wt %, or about 0.001 wt % to about 0.05 wt % in the photoresist composition.

The photoresist composition according to some embodiments may include an organometallic compound, which includes a metal-ligand bond between a metal core and an organic ligand, and at least one first organic ligand precursor, which includes a phosphonic acid group. In some embodiments, the photoresist composition according to some embodiments includes a combination of the at least one first organic ligand precursor and at least one second organic ligand precursor, the at least one first organic ligand precursor being different in chemical structure from the organic ligand of the organometallic compound and having a structure capable of forming a coordination complex with the metal core of the organometallic compound. The at least one first organic ligand precursor or the combination of the at least one first organic ligand precursor and the at least one second organic ligand precursor, which is included in the photoresist composition according to some embodiments, may generate various modified organometallic compounds due to a ligand exchange based on chemical equilibrium depending on the types and/or amounts of the organic ligand precursors in the photoresist composition. Therefore, during the storage and/or transport of the photoresist composition, or during a process of manufacturing an integrated circuit device by using the photoresist composition, the photoresist composition may be prevented from suffering from a change over time causing the photoresist composition to be unintentionally broken due to light or water in air. Thus, a reaction, in which the metal core of the organometallic compound reacts with water to generate a hydroxyl (—OH) group, may be suppressed, whereby the stability of the photoresist composition over time may be secured and the process stability of the process of manufacturing an integrated circuit device by using the photoresist composition may be secured. In addition, various modified organometallic compounds may be formed by a ligand exchange that is based on chemical equilibrium depending on the types and/or amounts of the organic ligand precursors. Therefore, when a photoresist film obtained from the photoresist composition is exposed to light, the exposure sensitivity in an exposed region of the photoresist film may improve. Therefore, the photosensitivity in the exposed region may be relatively easily adjusted in the manner of adjusting the type and/or amount of the organic ligand precursor in the photoresist composition, thereby selectively forming a metal structure network with a dense structure only in the exposed region of the photoresist film. Therefore, excellent resolution and improved sensitivity in a photolithography process may be provided, and the dimensional precision of a pattern intended to be formed may be improved by preventing the deterioration in CD distribution of the pattern obtained by a photolithography process.

The photoresist composition according to the inventive concept may be advantageously used in forming a pattern having a relatively high aspect ratio. For example, the photoresist composition according to the inventive concept may be advantageously used in a photolithography process of forming a pattern having a fine width selected from a range of about 5 nm to about 100 nm, for example, 5 nm, 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, or 100 nm, or less than about 100 nm, 95 nm, 90 nm, 85 nm, 80 nm, 75 nm, 70 nm, 65 nm, 60 nm, 55 nm, 50 nm, 45 nm, 40 nm, 35 nm, 30 nm, 25 nm, 20 nm, 15 nm or 10 nm.

Next, a method of manufacturing an integrated circuit device by using the photoresist composition according to some embodiments is described by taking a specific example.

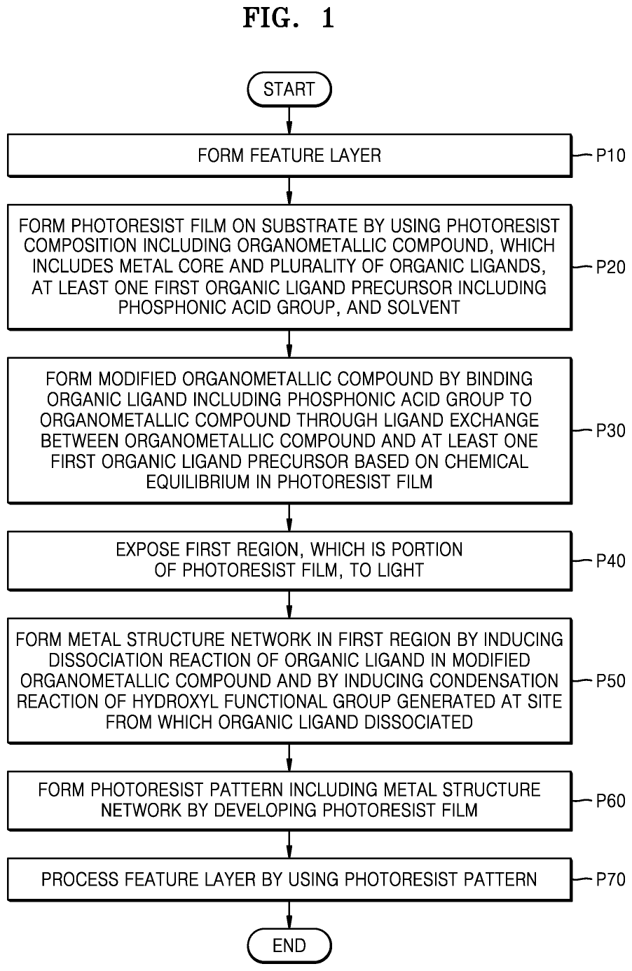

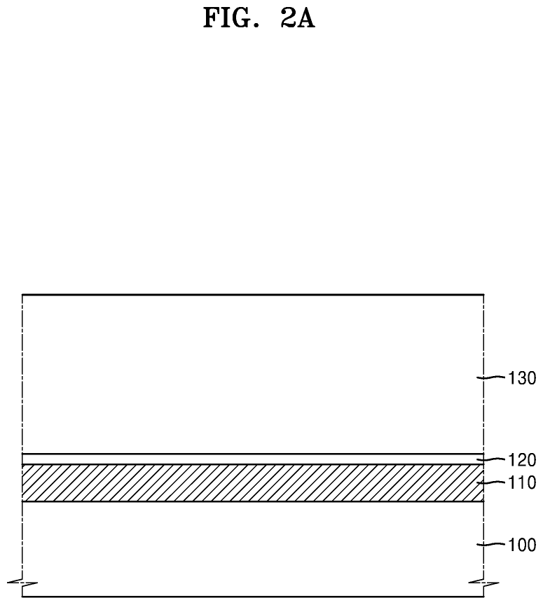

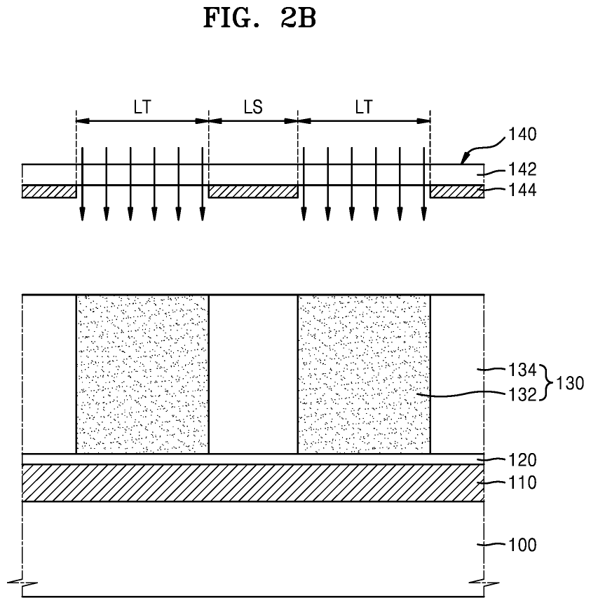

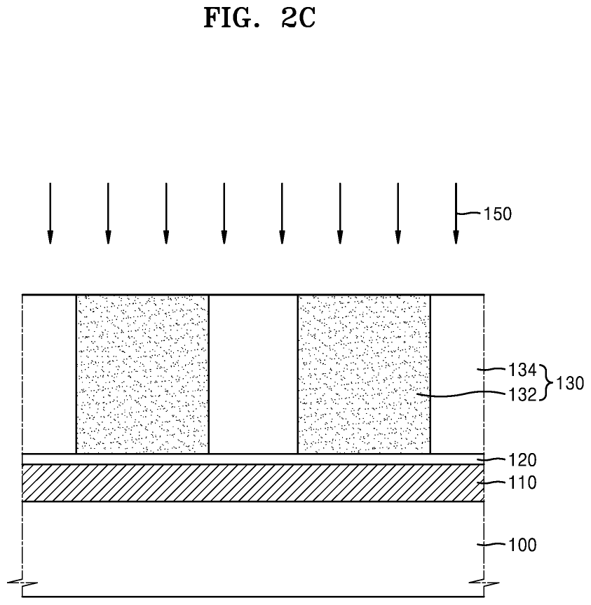

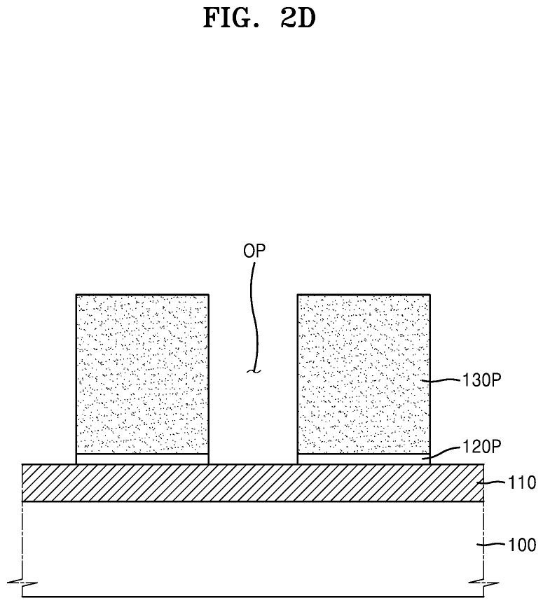

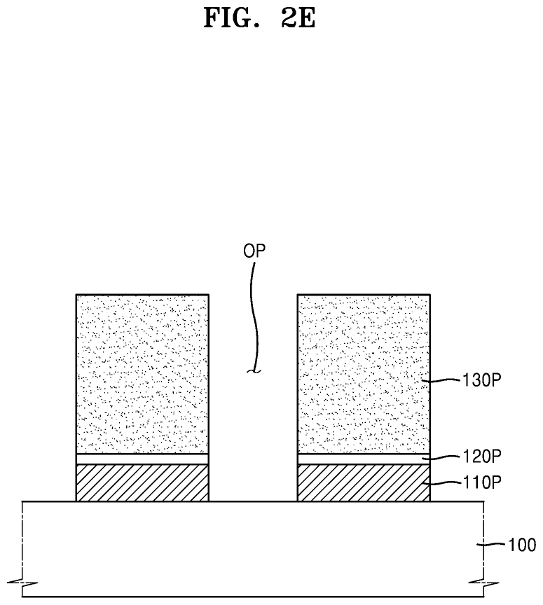

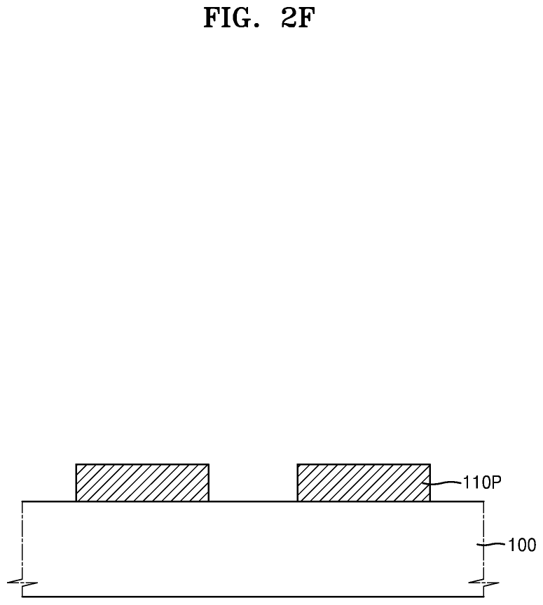

FIG. 1 is a flowchart illustrating a method of manufacturing an integrated circuit device, according to some embodiments. FIGS. 2A to 2F are cross-sectional views illustrating aspects of a method of manufacturing an integrated circuit device, according to some embodiments.

Referring to FIGS. 1 and 2A, in process P10, a feature layer 110 may be formed on a substrate 100. Next, in process P20, a photoresist film 130 may be formed on the feature layer 110 by using the photoresist composition according to some embodiments. A more detailed configuration of the photoresist composition is the same as described above.

The substrate 100 may include a semiconductor substrate. The feature layer 110 may include an insulating film, a conductive film, or a semiconductor film. For example, the feature layer 110 may include, but is not limited to, a metal, an alloy, a metal carbide, a metal nitride, a metal oxynitride, a metal oxycarbide, a semiconductor, polysilicon, an oxide, a nitride, an oxynitride, or any combination thereof.

In some embodiments, as shown in FIG. 2A, before the photoresist film 130 is formed on the feature layer 110, a lower film 120 may be formed on the feature layer 110. In this case, the photoresist film 130 may be formed on the lower film 120. The lower film 120 may prevent the photoresist film 130 from being adversely affected by the feature layer 110 under the photoresist film 130. In some embodiments, the lower film 120 may include an organic or inorganic anti-reflective coating (ARC) material for KrF excimer lasers, ArF excimer lasers, EUV lasers, or any other light sources. In some embodiments, the lower film 120 may include a bottom anti-reflective coating (BARC) film or a developable bottom anti-reflective coating (DBARC) film. In some embodiments, the lower film 120 may include an organic component having a light absorption structure. The light absorption structure may include, for example, a hydrocarbon compound having a structure in which one or more benzene rings are fused. The lower film 120 may have, but is not limited to, a thickness of about 1 nm to about 100 nm. In some embodiments, the lower film 120 may be omitted.

To form the photoresist film 130, the photoresist composition according to some embodiments may be coated on the lower film 120 and then treated with heat. The coating may be performed by a method, such as spin coating, spray coating, dip coating, or the like. A process of heat-treating the photoresist composition may be performed at a temperature of about 80° C. to about 300° C. for about 10 seconds to about 100 seconds, but the inventive concept is not limited thereto. The thickness of the photoresist film 130 may be tens to hundreds of times the thickness of the lower film 120. The photoresist film 130 may have, but is not limited to, a thickness of about 10 nm to about 1 m, for example, about 10 nm, about 20 nm, about 30 nm, about 40 nm, about 50 nm, about 60 nm, about 70 nm, about 80 nm, about 90 nm, about 100 nm, about 200 nm, about 300 nm, about 400 nm, about 500 nm, about 600 nm, about 700 nm, about 800 nm, about 900 nm, or about 1 m, or less than about 1 m, about 900 nm, about 800 nm, about 700 nm, about 600 nm, about 500 nm, about 400 nm, about 300 nm, about 200 nm, about 100 nm, about 90 nm, about 80 nm, about 70 nm, about 60 nm, about 50 nm, about 40 nm, about 30 nm, or about 20 nm.

After the photoresist film 130 is formed, or while the photoresist film 130 is formed, according to process P30 of FIG. 1, an organic ligand including a phosphonic acid group may be bonded to the organometallic compound due to a ligand exchange between the organometallic compound and the at least one first organic ligand precursor based on chemical equilibrium in the photoresist film 130, thereby forming a modified organometallic compound.

More specifically, the photoresist composition according to some embodiments may include an organometallic compound including a metal core and a plurality of organic ligands bonded to the metal core, at least one first organic ligand precursor including a phosphonic acid group, and a solvent, the at least one first organic ligand precursor being different in chemical structure from the plurality of organic ligands of the organometallic compound and having a structure capable of forming a coordination complex with the metal core. In some embodiments, in the organometallic compound, all or at least some of the plurality of organic ligands bonded to the metal core are devoid of a phosphonic acid group.

As described above, in the photoresist composition according to some embodiments, the at least one first organic ligand precursor may be different in chemical structure from the organic ligands of the organometallic compound, may include a phosphonic acid group, and may have a structure capable of forming a coordination complex with the metal core of the organometallic compound. Therefore, after the photoresist film 130 is formed, as in process P30 of FIG. 1, various modified organometallic compounds may be generated due to a ligand exchange based on chemical equilibrium in the photoresist composition depending on the type and amount of the at least one first organic ligand precursor. That is, an organic ligand including a phosphonic acid group may be bonded to the organometallic compound due to a ligand exchange between the organometallic compound and the at least one first organic ligand precursor based on chemical equilibrium in the photoresist film 130, thereby forming a modified organometallic compound.

Therefore, while the photoresist film 130 is formed according to process P20 of FIG. 1 with reference to FIG. 2A, or during a standby time period after the formation of the photoresist film 130 until a subsequent process, the photoresist film 130 may be prevented from suffering from a change over time causing the photoresist film 130 to be unintentionally broken due to light or water even when the photoresist film 130 is exposed to light or water in air, and thus, a reaction, in which the metal core reacts with water to generate a hydroxyl (—OH) group, may be suppressed, whereby the stability of the photoresist film 130 over time may be secured.

In some embodiments, when a photoresist composition including the at least one first organic ligand precursor and the at least one second organic ligand precursor is used to form the photoresist film 130, the combination of the at least one first organic ligand precursor and the at least one second organic ligand precursor may generate various modified organometallic compounds due to a ligand exchange based on chemical equilibrium depending on the types and/or amounts of the organic ligand precursors in the photoresist film 130. Therefore, until a subsequent exposure process is performed after the photoresist film 130 is formed, an unintended reaction in the photoresist film 130 due to light or water, for example, a reaction in which metal cores of the photoresist film 130 react with water to generate hydroxyl (—OH) groups, may be suppressed, and thus, the stability of the photoresist composition over time may be secured.

Referring to FIGS. 1 and 2B, in process P40, a first region 132, which is a portion of the photoresist film 130, may be exposed to light. As a result, in the first region 132, a dissociation reaction of the plurality of organic ligands in the organometallic compound, which is included in the photoresist film 130, may be induced, and a condensation reaction of hydroxyl (—OH) functional groups generated at sites, from which the organic ligands are dissociated, may be induced, thereby forming a metal structure network with a dense structure.

On the other hand, a metal structure network is not formed in a second region 134, which is a non-exposed region of the photoresist film 130, and thus, the difference in solubility in a developer between the first region 132 and the second region 134 of the photoresist film 130 may be increased.

In some embodiments, in the case where a photoinitiator is included in the photoresist film 130, when the first region 132, which is a portion of the photoresist film 130, is exposed to light according to process P30 of FIG. 1, an acid or a radical may be generated from the photoinitiator in the first region 132. The photoinitiator may include a PAG configured to generate an acid due to light, a PRG configured to generate a radical due to light, or a combination of a PAG and a PRG. Therefore, while the first region 132 of the photoresist film 130 is exposed to light according to process P30 of FIG. 1, the photoinitiator of the photoresist film 130 in the first region 132 may generate an acid and/or a radical by absorbing light.

In some embodiments, to expose the first region 132 of the photoresist film 130 to light, a photomask 140, which has a plurality of light shielding areas LS and a plurality of light transmitting areas LT, may be aligned at a certain position over the photoresist film 130, and the first region 132 of the photoresist film 130 may be exposed to light through the plurality of light transmitting areas LT of the photomask 140. To expose the first region 132 of the photoresist film 130, a KrF excimer laser (248 nm), an ArF excimer laser (193 nm), an F₂ excimer laser (157 nm), or an EUV laser (13.5 nm) may be used.

In some embodiments, the photomask 140 may include a transparent substrate 142 and a plurality of light shielding patterns 144 formed in the plurality of light shielding areas LS on the transparent substrate 142. The transparent substrate 142 may include quartz. The plurality of light shielding patterns 144 may include chromium (Cr). The plurality of light transmitting areas LT may be defined by the plurality of light shielding patterns 144. According to the inventive concept, to expose the first region 132 of the photoresist film 130 to light, a reflective photomask (not shown) for EUV exposure may be used instead of the photomask 140.

Referring to FIGS. 1 and 2C, in process P50, a bake process may be performed by applying heat 150 to the photoresist film 130 including the first region 132 that is exposed to light.

The bake process may be performed at a temperature of about 50° C. to about 400° C. for about 10 seconds to about 150 seconds. For example, the bake process may be performed at a temperature of about 150° C. to about 250° C. for about 60 seconds to about 120 seconds, but the inventive concept is not limited thereto. In some embodiments, the bake process is performed at a temperature of about 50° C., 60° C., 70° C., 80° C., 90° C., 100° C., 110° C., 120° C., 130° C., 140° C., 150° C., 160° C., 170° C., 180° C., 190° C., 200° C., 210° C., 220° C., 230° C., 240° C., 250° C., 260° C., 270° C., 280° C., 290° C., 300° C., 310° C., 320° C., 330° C., 340° C., 350° C., 360° C., 370° C., 380° C., 390° C., or 400° C., or more than about 140° C., 150° C., 160° C., 170° C., 180° C., 190° C., 200° C., 210° C., 220° C., 230° C., 240° C., or 250° C. In some embodiments, the bake process is performed for about 10, 20, 30, 40, 50, 60, 70, 80, 90, 100, 110, 120, 130, 140, or 150 seconds, or more than about 50, 60, 70, 80, 90, 100, 110, or 120 seconds.

In some embodiments, in the case where a photoinitiator is included in the photoresist film 130, while the bake process of the photoresist film 130 is performed, a dissociation reaction of an organic ligand in the organometallic compound may be induced by using an acid or a radical generated from the photoinitiator in the first region 132, and a condensation reaction of a hydroxyl (—OH) functional group generated at a site, from which the organic ligand is dissociated, may be induced, thereby forming a metal structure network having a dense structure.

On the other hand, no metal structure network is formed in the second region 134, e.g., the second region is devoid of, or substantially devoid of, a metal structure network, which is a non-exposed region of the photoresist film 130, and thus, the difference in solubility in a developer between the first region 132 and the second region 134 of the photoresist film 130 may be increased.

Referring to FIGS. 1 and 2D, in process P60, the second region 134 of the photoresist film 130 may be removed by developing the photoresist film 130 using a developer. As a result, a photoresist pattern 130P, which includes the metal structure network formed in the exposed first region 132 of the photoresist film 130, may be formed.

The photoresist pattern 130P may include a plurality of openings OP. After the photoresist pattern 130P is formed, a lower pattern 120P may be formed by removing portions of the lower film 120, which are exposed by the plurality of openings OP.

In some embodiments, the development of the photoresist film 130 may be performed by a negative-tone development (NTD) process.

In some embodiments, to develop the photoresist film 130, a developer including an organic solvent may be used. For example, the developer may include, but is not limited to, ketones, such as methyl ethyl ketone, acetone, cyclohexanone, and 2-heptanone; alcohols, such as 4-methyl-2-propanol, 1-butanol, isopropanol, 1-propanol, and methanol; esters, such as propylene glycol monomethyl ether acetate, ethyl acetate, ethyl lactate, n-butyl acetate, and butyrolactone; aromatic compounds, such as benzene, xylene, and toluene; or any combination thereof.

As described with reference to FIG. 2C, as the difference in solubility in the developer between the exposed first region 132 and the non-exposed second region 134 in the photoresist film 130 is increased, while the second region 134 is removed by developing the photoresist film 130 in the process of FIG. 2D, the first region 132 may remain intact without being removed. Therefore, after the photoresist film 130 is developed, residual defects, such as a footing phenomenon, may not occur, and a vertical sidewall profile of the photoresist pattern 130P may be obtained. As such, by improving the sidewall profile of the photoresist pattern 130P, a critical dimension of an intended processing region in the feature layer 110 may be precisely controlled when the feature layer 110 is processed by using the photoresist pattern 130P.

In some embodiments, after the photoresist pattern 130P is formed by developing the photoresist film 130, as described with reference to FIG. 2D, a process of performing hard bake on an obtained resulting product may be further performed. Through the hard bake process, unnecessary materials, such as the developer remaining on the resulting product in which the photoresist pattern 130P is formed, may be removed. In addition, during the bake process performed according to process P50 of FIG. 1 with reference to FIG. 2C, when a dissociation reaction of an organic ligand in the organometallic compound and an additional condensation reaction according thereto are not sufficiently performed, an additional reaction of the unreacted portions may be induced by the hard bake process. Therefore, the hardness of the photoresist pattern 130P may be further increased by the hard bake process.

The hard bake process may be performed at a temperature of about 50° C. to about 400° C. for about 10 seconds to about 150 seconds. For example, the hard bake process may be performed at a temperature of about 150° C. to about 250° C. for about 60 seconds to about 120 seconds, but the inventive concept is not limited thereto. In some embodiments, the hard bake process is performed at a temperature of about 50° C., 60° C., 70° C., 80° C., 90° C., 100° C., 110° C., 120° C., 130° C., 140° C., 150° C., 160° C., 170° C., 180° C., 190° C., 200° C., 210° C., 220° C., 230° C., 240° C., 250° C., 260° C., 270° C., 280° C., 290° C., 300° C., 310° C., 320° C., 330° C., 340° C., 350° C., 360° C., 370° C., 380° C., 390° C., or 400° C., or more than about 140° C., 150° C., 160° C., 170° C., 180° C., 190° C., 200° C., 210° C., 220° C., 230° C., 240° C., or 250° C. In some embodiments, the hard bake process is performed for about 10, 20, 30, 40, 50, 60, 70, 80, 90, 100, 110, 120, 130, 140, or 150 seconds, or more than about 50, 60, 70, 80, 90, 100, 110, or 120 seconds. In some embodiments, the bake process and hard bake process are performed at the same processing conditions, e.g., same temperature and time. In some embodiments, the bake process and the hard bae process are performed at different processing conditions, e.g., different temperature and/or time.

Referring to FIGS. 1 and 2E, in process P70, in the resulting product of FIG. 2D, the feature layer 110 may be processed by using the photoresist pattern 130P.

To process the feature layer 110, various processes, such as a process of etching the feature layer 110 exposed by an opening OP of the photoresist pattern 130P, a process of implanting impurity ions into the feature layer 110, a process of forming an additional film on the feature layer 110 through the opening OP, and a process of modifying a portion of the feature layer 110 through the opening OP, may be performed. Although FIG. 2E illustrates, as an example of a process of processing the feature layer 110, an example of forming a feature pattern 110P by etching the feature layer 110 exposed by the opening OP, the inventive concept is not limited thereto.

In some embodiments, the process of forming the feature layer 110 may be omitted from the process described with reference to FIG. 2A, and in this case, instead of the process P70 of FIG. 1 and the process described with reference to FIG. 2E, the substrate 100 may be processed by using the photoresist pattern 130P. For example, various processes, such as a process of etching a portion of the substrate 100 by using the photoresist pattern 130P, a process of implanting impurity ions into a portion of the substrate 100, a process of forming an additional film on the substrate 100 through the opening OP, and a process of modifying a portion of the substrate 100 through the opening OP, may be performed.

Referring to FIG. 2F, in the resulting product of FIG. 2E, the photoresist pattern 130P and the lower pattern 120P, which remain on the feature pattern 110P, may be removed. To remove the photoresist pattern 130P and the lower pattern 120P, ashing and strip processes may be used.

According to the method of manufacturing an integrated circuit device, which is described with reference to FIGS. 1 and 2A to 2F, the difference in solubility in a developer between the exposed region and the non-exposed region of the photoresist film 130, which is obtained by using the photoresist composition according to the inventive concept, may be increased, and the CD distribution in the photoresist pattern 130P may improve. Therefore, when a subsequent process is performed on the feature layer 110 and/or the substrate 100 by using the photoresist pattern 130P, CDs of processing regions or patterns intended to be formed in the feature layer 110 and/or the substrate 100 may be precisely controlled, thereby improving dimensional precision. In addition, the CD distribution of patterns intended to be implemented on the substrate 100 may be uniformly controlled, and the productivity of a manufacturing process of an integrated circuit device may improve.

Next, examples in which properties of the photoresist composition according to some embodiments are evaluated, are described. For such evaluations, photoresist patterns were formed of photoresist compositions having various configurations according to some embodiments, and CD standard deviations in the obtained photoresist patterns were evaluated.

Table 1 shows results of evaluating CD standard deviations in the obtained photoresist patterns, depending on the amount of an organic ligand precursor including a phosphonic acid group from among organic ligand precursors, when the photoresist pattern is formed from each of the photoresist compositions including an organometallic compound, which includes a metal core including tin (Sn), and various organic ligand precursors.

More specifically, in Table 1, Example 1 is an example of including butyric acid (CH₃(CH₂)₂COOH) (hereinafter, referred to as C1) as the organic ligand precursor, and each of Example 2 and Example 3 is an example of including a combination of butyric acid (C1) and propylphosphonic acid (hereinafter, referred to as P1) as the organic ligand precursor, wherein Example 2 and Example 3 are different from each other in the molar ratio of each of butyric acid (C1) and propylphosphonic acid (P1) with respect to the organometallic compound. In Table 1, the respective molar ratios of butyric acid (C1) and propylphosphonic acid (P1) to the organometallic compound are listed together, and the CD standard deviations are shown as relative values when the CD standard deviation in Example 1 is taken to be 1.00.

TABLE 1

| | Example 1 | Example 2 | Example 3 |
|---|---|---|---|
| | C1 (molar | C1 (molar | C1 (molar |
| | ratio = 1.02) | ratio = 1) | ratio = 0.98) |
| | P1 (molar | P1 (molar | P1 (molar |
| | ratio = 0) | ratio = 0.02) | ratio = 0.04) |
| CD standard deviation | 1.00 | 0.978 | 0.944 |

From the results of Table 1, it can be seen that the CD standard deviation decreases along with the increasing amount of an organic ligand precursor, which includes a phosphonic acid group, from among the organic ligand precursors of the photoresist composition. That is, as the amount of the organic ligand precursor including a phosphonic acid group increases in the photoresist composition according to the inventive concept, the deterioration in the CD distribution of the obtained photoresist pattern may be further prevented and the dimensional precision of a pattern intended to be formed may further improve.

While the inventive concept has been particularly shown and described with reference to embodiments thereof, it will be understood that various changes in form and details may be made therein without departing from the spirit and scope of the following claims.

What is claimed is:

1. A photoresist composition comprising:
an organometallic compound that comprises at least one metal-ligand bond comprising a metal core and at least one organic ligand bonded to the metal core;
at least one first organic ligand precursor that has a different chemical structure than the at least one organic ligand of the organometallic compound, and wherein the at least first organic ligand precursor comprises a phosphonic acid group and has a structure capable of forming a coordination complex with the metal core; and
a solvent.

2. The photoresist composition of claim 1, wherein the at least one first organic ligand precursor comprises an organic phosphonic acid compound of General Formula 1:
$${R}^{1} — P ( = O ) {( OH )}_{2} \qquad [ General Formula 1 ]$$
wherein:
R¹ is an aliphatic hydrocarbon group or an aromatic hydrocarbon group selected from a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, or a substituted or unsubstituted C7 to C30 alkylaryl group, and
when R¹ has a substituted hydrocarbon group, all or some hydrogen atoms, which are comprised in the hydrocarbon group of R¹, are independently substituted with a halogen atom, a hydroxyl group, a sulfonic acid group, a carboxyl group, an amino group, a thiol (—SH) group, an R¹¹SO₃— group, or an R¹²SO₂— group, wherein R¹¹ and R¹² are each independently a hydrogen atom, a substituted or unsubstituted C1 to C10 alkyl group, or a substituted or unsubstituted phenyl group.

3. The photoresist composition of claim 2, wherein R¹ is a substituted or unsubstituted C1 to C30 linear alkyl group, a substituted or unsubstituted C1 to C30 branched alkyl group, a substituted or unsubstituted C2 to C30 alkenyl group, or a substituted or unsubstituted C2 to C30 alkynyl group.

4. The photoresist composition of claim 2, wherein R¹ is a substituted or unsubstituted C3 to C30 cycloalkyl group, a substituted or unsubstituted C6 to C30 aryl group, a substituted or unsubstituted C2 to C30 heteroaryl group, or a substituted or unsubstituted C7 to C30 alkylaryl group.

5. The photoresist composition of claim 1, wherein a molar ratio of the at least one first organic ligand precursor to the organometallic compound is about 0.01 to about 10.

6. The photoresist composition of claim 1, further comprising at least one second organic ligand precursor that comprises an organic carboxylic acid compound, wherein the at least one second organic ligand precursor has a structure of General Formula 2:
R²—COOH [General Formula 2]
wherein:
R² is an aliphatic hydrocarbon group or an aromatic hydrocarbon group selected from a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 alkylaryl group, and a substituted or unsubstituted C7 to C30 arylalkyl group, and
when R² has a substituted hydrocarbon group, all or some hydrogen atoms, which are comprised in the hydrocarbon group of R², are independently substituted with a halogen atom, a hydroxyl group, a sulfonic acid group, an amino group, or a thiol (—SH) group.

7. The photoresist composition of claim 6, wherein a molar ratio of the at least one second organic ligand precursor to the organometallic compound is about 0.01 to about 10.

8. The photoresist composition of claim 6, wherein the at least one second organic ligand precursor is selected from acetic acid, propionic acid, butyric acid, isobutyric acid, pivalic acid, valeric acid, caproic acid, benzoic acid, and a combination thereof.

9. The photoresist composition of claim 1, wherein the metal core comprises at least one metal element selected from Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, and Fe.

10. The photoresist composition of claim 1, wherein the organometallic compound has a structure of General Formula 3: 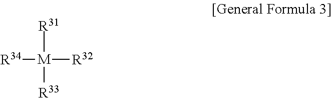
wherein:
M is Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe, and
R³¹, R³², R³³, and R³⁴ are each independently a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, a —R³¹—O—R³⁶ group, wherein R³⁵ is a substituted or unsubstituted C1 to C20 alkylene group and R³⁶ is a substituted or unsubstituted C1 to C20 alkyl group, an R³⁷—COO— group, an R³⁷—SO₃— group, or an R³⁷—SO₂— group, wherein R³⁷ is a substituted or unsubstituted C1 to C10 alkyl group or a substituted or unsubstituted phenyl group.

11. The photoresist composition of claim 10, wherein, in General Formula 3, R³¹ is a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a —R³⁵—O—R³⁶ group, wherein R³⁵ is a substituted or unsubstituted C1 to C20 alkylene group and R³⁶ is a substituted or unsubstituted C1 to C20 alkyl group, and
R³², R³³, and R³⁴ are each independently an R³⁷—COO— group.

12. A photoresist composition comprising:
an organometallic compound that comprises a metal core and a plurality of organic ligands bonded to the metal core;
at least one first organic ligand precursor that has a different chemical structure than the plurality of organic ligands of the organometallic compound, and wherein the at least one first organic ligand precursor comprises a phosphonic acid group and has a structure capable of forming a coordination complex with the metal core; and
a solvent,
wherein one organic ligand of the plurality of organic ligands is a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, or a substituted or unsubstituted C7 to C30 arylalkyl group, and the other organic ligands of the plurality of organic ligands are each independently an R³⁷COO— group, wherein each R³⁷ is independently a substituted or unsubstituted C1 to C10 alkyl group or a substituted or unsubstituted phenyl group, and
wherein a molar ratio of the at least one first organic ligand precursor to the organometallic compound is about 0.01 to about 10.

13. The photoresist composition of claim 12, wherein the at least one first organic ligand precursor comprises an organic phosphonic acid compound of General Formula 1:
$${R}^{1} — P ( = O ) {( OH )}_{2} \qquad [ General Formula 1 ]$$
wherein:
R¹ is an aliphatic hydrocarbon group or an aromatic hydrocarbon group selected from a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, and a substituted or unsubstituted C7 to C30 alkylaryl group, and
when R¹ has a substituted hydrocarbon group, all or some hydrogen atoms, which are comprised in the hydrocarbon group of R¹, are independently substituted with a halogen atom, a hydroxyl group, a sulfonic acid group, a carboxyl group, an amino group, a thiol (—SH) group, an R¹¹SO₃— group, or an R¹²SO₂— group, wherein R¹¹ and R¹² are each independently a hydrogen atom, a substituted or unsubstituted C1 to C10 alkyl group, or a substituted or unsubstituted phenyl group.

14. The photoresist composition of claim 13, wherein, in General Formula 1, R¹ is a substituted or unsubstituted C1 to C30 linear alkyl group, a substituted or unsubstituted C1 to C30 branched alkyl group, a substituted or unsubstituted C2 to C30 alkenyl group, or a substituted or unsubstituted C2 to C30 alkynyl group.

15. The photoresist composition of claim 13, wherein, in General Formula 1, R¹ is a substituted or unsubstituted C3 to C30 cycloalkyl group, a substituted or unsubstituted C6 to C30 aryl group, a substituted or unsubstituted C2 to C30 heteroaryl group, or a substituted or unsubstituted C7 to C30 alkylaryl group.

16. The photoresist composition of claim 12, further comprising at least one second organic ligand precursor that comprises an organic carboxylic acid compound, wherein the at least one second organic ligand precursor has a structure of General Formula 2:
R²—COOH [General Formula 2]
wherein:
R² is an aliphatic hydrocarbon group or an aromatic hydrocarbon group selected from a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 alkylaryl group, and a substituted or unsubstituted C7 to C30 arylalkyl group, and
when R² has a substituted hydrocarbon group, all or some hydrogen atoms, which are comprised in the hydrocarbon group of R², are independently substituted with a halogen atom, a hydroxyl group, a sulfonic acid group, an amino group, or a thiol (—SH) group,
wherein a molar ratio of the at least one second organic ligand precursor to the organometallic compound is about 0.01 to about 10.

17. A method of manufacturing an integrated circuit device, the method comprising:
forming a photoresist film on a substrate using a photoresist composition comprising an organometallic compound, at least one first organic ligand precursor, and a solvent, the organometallic compound comprising a metal core and a plurality of organic ligands that are bonded to the metal core and each is devoid of a phosphonic acid group, and wherein the at least one first organic ligand precursor has a different chemical structure than the plurality of organic ligands of the organometallic compound, comprises a phosphonic acid group, and has a structure capable of forming a coordination complex with the metal core;
forming a modified organometallic compound by binding an organic ligand comprising a phosphonic acid group to the organometallic compound through a ligand exchange between the organometallic compound and the at least one first organic ligand precursor based on chemical equilibrium in the photoresist film;
exposing a first region, which is a portion of the photoresist film, to light to provide an exposed first region;
forming a metal structure network in the first region by inducing a dissociation reaction of the organic ligand from the modified organometallic compound in the first region through bake of the photoresist film comprising the exposed first region and by inducing a condensation reaction of a hydroxyl (—OH) functional group generated at a site from which the organic ligand is dissociated in the modified organometallic compound; and
forming a photoresist pattern comprising the metal structure network by developing the photoresist film in which the metal structure network is formed.

18. The method of claim 17, wherein the at least one first organic ligand precursor comprises an organic phosphonic acid compound of General Formula 1:
$${R}^{1} — P ( = O ) {( OH )}_{2} \qquad [ General Formula 1 ]$$
wherein:
R¹ is an aliphatic hydrocarbon group or an aromatic hydrocarbon group selected from a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, and a substituted or unsubstituted C7 to C30 alkylaryl group, and
when R¹ has a substituted hydrocarbon group, all or some hydrogen atoms, which are comprised in the hydrocarbon group of R¹, are independently substituted with a halogen atom, a hydroxyl group, a sulfonic acid group, a carboxyl group, an amino group, a thiol (—SH) group, an R¹¹SO₃— group, or an R¹²SO₂— group, wherein R¹¹ and R¹² are each independently a hydrogen atom, a substituted or unsubstituted C1 to C10 alkyl group, or a substituted or unsubstituted phenyl group.

19. The method of claim 18, wherein, in General Formula 1, R¹ is a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C6 to C30 aryl group, a substituted or unsubstituted C2 to C30 heteroaryl group, or a substituted or unsubstituted C7 to C30 alkylaryl group.

20. The method of claim 17, further comprising at least one second organic ligand precursor that comprises an organic carboxylic acid compound, wherein the at least one second organic ligand precursor has a structure of General Formula 2:
R²—COOH [General Formula 2]
wherein:
R² is an aliphatic hydrocarbon group or an aromatic hydrocarbon group selected from a substituted or unsubstituted C1 to C30 linear alkyl group, a substituted or unsubstituted C1 to C30 branched alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 alkylaryl group, and a substituted or unsubstituted C7 to C30 arylalkyl group, and
when R² has a substituted hydrocarbon group, all or some hydrogen atoms, which are comprised in the hydrocarbon group of R², are independently substituted with a halogen atom, a hydroxyl group, a sulfonic acid group, an amino group, or a thiol (—SH) group).
